(19) United States
(12) Patent Application Publication
(10) Pub. No.: US 2008/0014667 A1
(43) Pub. Date: Jan. 17, 2008

(54) MODIFYING THE OPTICAL PROPERTIES OF A NITRIDE OPTOELECTRONIC DEVICE

(76) Inventors: Stewart Edward HOOPER, Oxford (GB); Matthias Kauer, Oxford (GB); Jonathan Heffernan, Oxford (GB); Joanna Catherine Alderman, Tewkesbury (GB); Jennifer Mary Barnes, Oxford (GB); Valerie Bousquet, Norton (GB); Takeshi Kamikawa, Mihara-shi (JP); Yoshiyuki Takahira, Mihara-shi (JP)

Correspondence Address: MARK D. SARALINO ( SHARP );RENNER, OTTO, BOISSELLE & SKLAR, LLP, 1621 EUCLID AVENUE, 19TH FLOOR, CLEVELAND, OH, 44115, US

(21) Appl. No.: 11/774,662

(22) Filed: Jul. 9, 2007

(30) Foreign Application Priority Data
Jul. 13, 2006 (GB) GB 0613890.3

(51) Int. Cl. H01L 33/00

(52) U.S. Cl. 438/31; 257/E33.068

(57) ABSTRACT

A method of modifying the optical properties of a processed nitride semiconductor light-emitting device initially comprises disposing the processed nitride semiconductor light-emitting device in a vacuum chamber. One or more nitride semiconductor layers are then grown by molecular beam epitaxy thereby to modify the optical properties of the processed light-emitting device. Activated nitrogen, for example from a plasma source, is supplied to the vacuum chamber during growth of the nitride semiconductor layer(s). The use of activated nitrogen reduces the growth temperature required for the growth of the nitride semiconductor layer(s), as the need for thermal activation of a nitrogen species is eliminated. Moreover, use of a growth method such as, for example, plasma-assisted MBE to grow the nitride semiconductor layer(s) allows much more precise control of their thickness and composition.

This Nonprovisional application claims priority under 35 U.S.C. § 119(a) on British Patent Application No. 0613890.3 filed in U.K. on 13 Jul. 2006, the entire contents of which are hereby incorporated by reference.

### FIELD OF THE INVENTION

The present invention relates to a method of modifying the optical properties of a nitride optoelectronic device such as, for example, a nitrides laser diode or a nitrides light-emitting diode. It particularly relates to a method in which one or more nitride semiconductor layers are grown over the nitride optoelectronic device so as to modify the optical emission properties of the device.

### BACKGROUND OF THE INVENTION

Fabrication of an optoelectronics device in a nitride semiconductor system, such as the (Al,Ga,In)N materials system for example, is well-known. In summary, a semiconductor layer structure in the form of a “wafer” is grown in a suitable growth apparatus. The as-grown wafer has a typical diameter of 5 cm. After removal of the wafer from the growth apparatus, the wafer is then processed to form individual optoelectronic devices. Processing the wafer to form individual devices may include some or all of the following steps:

dividing, or “dicing”, the wafer into smaller areas, for example into areas corresponding to an individual device;

cleaving to define an output facet for light emission;

etching;

annealing, for example to activate dopants in one or more layers of the layer structure;

deposition, for example of electrical contacts;

patterning;

implantation, for example of dopant species to alter the electrical conductivity of part of the device; and

oxidation, for example to define an electrically insulating oxide layer.

Once a wafer has been processed into individual devices, it is often desired to grow one or more further semiconductor layers over an individual device. As one example, the cleaved facets of a semiconductor laser device are prone to suffer catastrophic optical damage (“COD”) as a result of heat generation at the air-facet interface leading to localised heating of the facet and degradation of the laser diode's light-emitting region which is a constituent part of the facet. To reduce the risk of COD, it is known to overgrow a semiconductor layer over the facet so as to move the air-semiconductor interface, and any localised heat generated at the interface, away from the light-emitting region of the laser diode. As a further example, it is known to grow a semiconductor layer over the light-emitting facet(s) of an optoelectronic device in order to modify the optical emission properties of the device.

U.S. patent application 2004/0238810 describes a method of overgrowing a semiconductor layer over an AlGaN facet of a laser device using the “AMMONO” technique. The AMMONO method consists of crystallization of AlGaN by a metal reaction with highly chemically active supercritical ammonia—the laser device is placed in an autoclave where a differential in temperature and super-saturation of ammonia induces growth by seeding on the laser facet. This method has a number of disadvantages such as, for example, a low deposition rate (typically, 3 days are required to deposit a layer) and the lack of precise control of the thickness or composition of the deposited overgrowth layer.

U.S. patent application No. 2002/0137236A1 discloses a transistor device with an AlN surface passivation layer that is deposited at low temperature by RF-molecular beam epitaxy (RF-MBE). This does not however relate to optoelectronic devices or light-emitting devices.

U.S. No. 2006/0133442 discloses a method of providing a facet coating on a nitride semiconductor laser bar. The method includes treating the cleaved surfaces of the laser bar with a plasma in order to remove moisture and oxide film from the facet, and then growing an adhesion layer and a facet coating layer over the facet again by means of a plasma treatment.

JP 2002-335053 relates to a method of plasma treatment of a laser facet.

WO 2003/044571 relates to the provision of coatings (such as anti-reflection coatings) on laser facets. It teaches a method in which the facets for a number of lasers are defined in a wafer, the facets are all coated in a single step, and the wafer is then cleaved. This allows the steps of defining the facet and applying the coating to be carried out in a controlled environment.

### SUMMARY OF THE INVENTION

The present application provides a method of modifying the optical properties of a processed nitride semiconductor light-emitting device, the method comprising the steps of:

a) disposing the processed nitride semiconductor light emitting device in a vacuum; and

b) growing one or more nitride semiconductor layers on said processed nitride semiconductor light-emitting device by molecular beam epitaxy thereby to modify the optical properties of the processed light-emitting device;

wherein the method further comprises supplying activated nitrogen to the vacuum chamber in step (b).

The term “optical properties” of the device as used herein includes any of the following (referring to the radiation emitted by the device): wavelength, intensity, polarisation, spectral width, spectral shape, pulsation (frequency and duration), mode pattern and shape. The or each nitride layer may be, for example, a layer of AlₓGa_{y}In_{1-x-y}N, where 0≦x≦1, 0≦y≦1, x+y≦1.

A method of the invention uses a growth method such as, for example, plasma-assisted MBE to grow the one or more nitride semiconductor layers over the nitride semiconductor light-emitting device. This allows much more precise control of the thickness and composition of the or each nitride semiconductor layer. The method of the invention also allows the nitride semiconductor layer(s) to be grown in a much shorter time than is required for the AMMONO method.

The invention makes possible the modification, by overgrowth of one or more nitride semiconductor layers, of the optical properties of a processed nitride light-emitting device. This leads to novel and improved optical characteristics and performance of the device such as, for example, high power blue lasers for recordable blu-ray DVD.

Moreover, the one or more nitride semiconductor layers can be grown at temperatures below the temperature at which damage to the processed device might occur. For example, a nitride laser diode structure with metal electrodes typically cannot be heated significantly above 500° C. without some degradation of the metal-semiconductor contacts occurring. It has accordingly been difficult to conceive using MBE to overgrow layers on a nitride device, because MBE growth of nitride semiconductor layers has conventionally been carried out at temperatures in excess of 500° C. in order to obtain high-quality material. The present invention makes possible the use of MBE to overgrow high quality nitride semiconductor layers, but at temperatures below 500° C. so that damage to the device is avoided. In principle, the growth temperature during the overgrowth of the nitride semiconductor layer(s) by the method of the invention may be as low as 30° C. (It should be noted that the maximum possible growth temperature during the overgrowth of the nitride semiconductor layer(s) is generally determined by the nature of the processed structure, so that growth temperatures above 500° C. may be used in cases where such temperatures will not cause damage to the specific device on which the layers are grown).

By making possible the use of MBE to overgrow high quality layers, but at growth temperatures at which damage to the device is avoided, the invention allows all advantages of MBE growth to be realised. These advantages include, for example: the precise control of layer thickness and composition that is possible with MBE growth; the possibility of depositing ternary or quaternary alloys by MBE, whereas conventional sputter deposition can only deposit binary alloys; and the possibility of doping layers grown by MBE if desired, so that a layer may be made either electrically-conducting or electrically-insulating as desired.

Step (b) may comprise growing the one or more nitride semiconductor layers by plasma-assisted molecular beam epitaxy.

Step (b) may comprise growing the one or more nitride semiconductor layers over a light-emitting facet of the light-emitting device. This allows the layer(s) to act as protection layers for the facet, or to modify the emission wavelength, or emission wavelength range, of the device.

The or each nitride semiconductor layer may have a bandgap greater than the emission photon energy of the light-emitting device. In this embodiment, the nitride semiconductor layer(s) may act as protection layers for the light-emitting facet, to reduce the risk of the facet suffering catastrophic optical damage when the device is in use.

At least one of the nitride semiconductor layer(s) may be, in use, optically excited by light emitted by the light-emitting device. In this embodiment it is possible to modify the emission wavelength, or emission wavelength range, of the device.

The or each nitride semiconductor layer may contain a photoluminescent species.

Step (b) may comprise growing a nitride semiconductor layer containing two or more photoluminescent species. In this embodiment the overall light output will include light re-emitted by each of the photoluminescent species, and any of the original light output from the device that was not absorbed by the photoluminescent species. By choosing the photoluminescent species accordingly, any desired output emission spectrum may be obtained—in particular, a white light output can be obtained.

Step (b) may alternatively comprise growing two or more nitride semiconductor layers each containing a respective photoluminescent species.

Step (b) may alternatively comprise growing the nitride semiconductor layer(s) over nanocrystals deposited on the processed nitrides semiconductor light-emitting device. The emission wavelength of a nanocrystal depends on the size of the nancrystal so, by varying the size of the nanocrystals, any desired output emission spectrum may be obtained.

The nanocrystals deposited on the processed nitrides semiconductor light-emitting device may comprise at least first nanocrystals having a first size and second nanocrystals having a second size different from the first size. The first and second nanocrystals will, as a result of their different sizes, have different emission wavelengths from one another. By choosing the sizes of the first and second nanocrystals accordingly, any desired output emission spectrum may be obtained.

The nitride semiconductor layer(s) may comprise at least one saturable absorbing layer. This embodiments allows a self-pulsation laser device to be obtained.

The nitride semiconductor layer(s) may define an optical cavity. This provides an optically-pumped device, in which the optical cavity is optically-pumped by light from the light-emitting device.

Step (b) may comprise depositing a plurality of nitride semiconductor layers, and at least one of the nitride semiconductor layers may, in use, be optically excited by light emitted by the light-emitting device. This embodiment allows a self-pulsation laser device to be obtained.

The nitride semiconductor layer(s) may define a wavelength filter. The wavelength filter transmits light only in a very narrow frequency range, and acts to filter light emitted by the light-emitting device. It is possible to obtain single wavelength output.

The nitride semiconductor layer(s) may comprise a light-sensitive layer, and may define a photodiode. The light sensitive layer or photodiode may be used to monitor or measure the light output from the device.

The processed nitride semiconductor light-emitting device may comprises a ridge waveguide, and step (b) may comprises growing the one or more nitride semiconductor layers over the surface of the device on which the ridge waveguide is provided. Growing one or more nitride semiconductor layers having a high thermal conductivity over the light-emitting device reduces the thermal resistance of the device, thereby allowing a higher optical power and better mode control to be obtained.

The or each nitride semiconductor layer may be electrically insulating, so that the layer(s) do not affect the current path through the light-emitting device.

### BRIEF DESCRIPTION OF THE DRAWINGS

Preferred embodiments of the present invention will be described by way of illustrative example with reference to the accompany figures in which:

FIGS. 1(a) to 1(c) provide a schematic illustration of the principal stages of a method of the present invention;

FIG. 2 is a schematic sectional view of a light-emitting device modified by a method of the invention;

FIGS. 3(a) to 3(c) are schematic sectional views of steps of another method of the invention;

FIG. 4 is a schematic sectional view of a light-emitting device modified by another method of the invention;

FIGS. 5(a) and 5(b) show EL and PL spectra for rare earth elements;

FIGS. 6(a) to 6(d) are schematic views of structures for encapsulating rare earth elements and nanocrystals in a device according to a method of the invention;

FIGS. 7(a) and 7(b) are schematic sectional views of laser devices modified by another method of the invention;

FIG. 8 is a schematic sectional view of a light-emitting device modified by a method of the invention by providing an optically pumped laser structure on a light-emitting facet;

FIGS. 9(a) and 9(b) are schematic sectional views of buried heterostructure laser devices modified by another method of the invention;

FIG. 10 is a schematic sectional view of a prior art buried heterostructure laser device;

FIG. 11 is a schematic sectional view of a light-emitting device modified by a method of the invention by providing an optical cavity on a light-emitting facet;

FIG. 12 is a schematic sectional view of a light-emitting device modified by a method of the invention by providing a photodiode on a light-emitting facet; and

FIG. 13 is a schematic view of a prior art polychromatic light-emitting diode.

### DESCRIPTION OF THE EMBODIMENTS

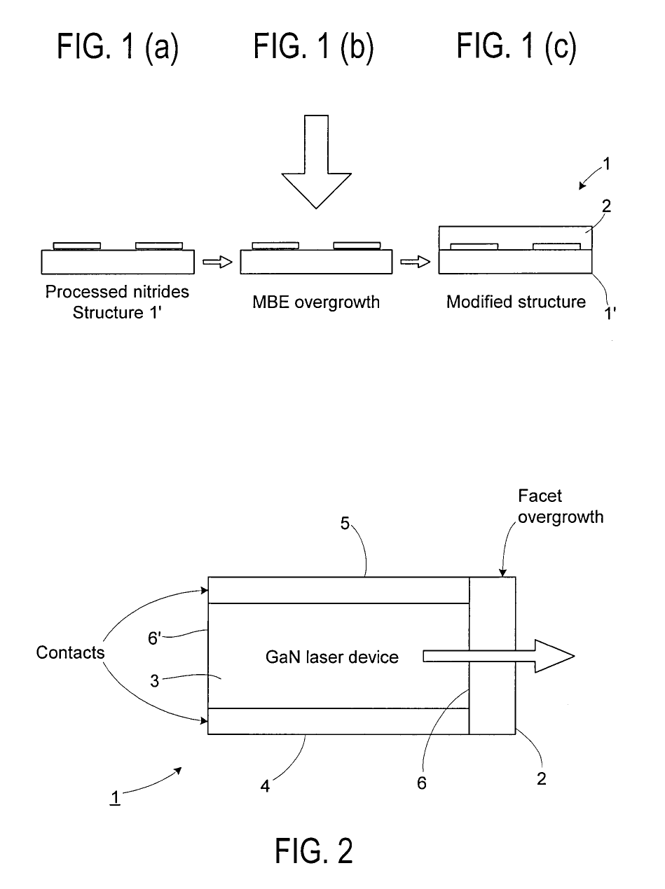

According to the present invention a plasma-assisted growth method, such as, for example, plasma-assisted MBE, is used to grow one or more nitride semiconductor layers over a processed semiconductor optoelectronic device, in order to modify its optical emission properties. FIG. 1(a) to FIG. 1(c) illustrate the principal stages of a method of the present invention.

The invention takes as its starting point a nitride semiconductor light-emitting device structure 1′ that has been processed in some way. The light-emitting device structure 1′ may have been grown according to any conventional semiconductor growth technique such as metal organic chemical vapour deposition (MOCVD) or molecular beam epitaxy. A processed semiconductor optoelectronic device is defined as a structure that has been converted from its “as-grown form” by one or more of: dicing, cleaving, etching, annealing, deposition, patterning, implantation or oxidation.

A processed nitride optoelectronic device structure is shown in FIG. 1(a).

The processed nitride semiconductor optoelectronic device is then introduced into a vacuum chamber, such as, for example, the growth chamber of a MBE growth apparatus. Overgrowth of one or more layers of nitride semiconductor material is carried out in the vacuum chamber, as indicated schematically in FIG. 1(b).

Activated nitrogen is used to supply the nitrogen species for the overgrowth of the nitride semiconductor layer(s). The activated nitrogen may be generated by, for example, a plasma source cell.

The growth temperature during the overgrowth of the one or more nitride semiconductor layers is generally determined by the nature of the processed structure. For example, a nitride laser diode structure with metal electrodes typically cannot be heated above 500° C. without some degradation of the metal-semiconductor contacts occurring. In principle, however, the growth temperature during the overgrowth of the nitride semiconductor layer(s) may be anywhere in the range from 30° C. to 1100° C.

The result of the invention is to deposit one or more nitride semiconductor layers, indicated generally as 2 in FIG. 1(c) over the processed nitride device structure 1′ thereby to produce a modified nitride semiconductor optoelectronic device structure 1. The nitride semiconductor layer(s) 2 modify the optical emission properties of the processed semiconductor optoelectronic device 1, compared with the optical emission properties of the original processed nitride device structure 1′, as will be described below.

The modified nitride semiconductor optoelectronic device structure 1 may then undergo further processing steps if necessary, in order to complete the fabrication of individual optoelectronic devices. The invention is not limited to a single overgrowth step, and multiple processing and overgrowth steps can be carried out. As an example, the modified nitride semiconductor optoelectronic device structure 1 shown in FIG. 1(c) may undergo one or more further processing steps, followed by a further step of overgrowing one or more nitride semiconductor layers.

FIG. 2 is a schematic cross-sectional view a modified nitride optoelectronic device 1 obtained by a method of the present invention. In this embodiment, one or more nitride semiconductor layers 2 are grown over a light-emitting facet 6 of a processed nitride laser device. The processed laser device contains a nitride semiconductor laser structure 3, and first and second contact 4,5 disposed on upper and lower surfaces of the laser structure 3.

It is known that catastrophic optical damage (COD) can occur within the facets of a semiconductor laser device operation, as a result of heat generation occurring at the air-facet interface leading to localised heating of the facet and degradation of the light-emitting region of the laser diode which is a constituent part of the facet. It has been proposed to reduce the risk of COD by deposition of a window region over the laser facet, with the window region being made of a semiconductor layer having a band gap greater than the photon energy of the laser. For example, U.S. Pat. No. 5,228,047 teaches deposition of a window region having a thickness of between 0.2 nm and 3 mm, so as to move the air-semiconductor interface and any localised heat generated at that interface away from the light-emitting region of the laser diode. The thickness of the window is chosen to prevent the formation of crystal defects arising owing to lattice mis-matching between the semiconductor material of the window layer and the semiconductor material at the laser facet. A similar structure is disclosed by K. Sasaki in Japanese Journal of Applied Physics, Vol. 30, No. 5B, L904 (1991). This describes use of a growth temperature of 800° C. to grow a good crystal quality AlGaAs layer on the facets of a laser device fabricated in the AlGaAs system. The high deposition temperature (which is similar to the device growth temperature) is required to prevent the formation of defects. Use of a growth temperature of 800° C. is, however, likely to cause damage to the processed laser device, in particular to any metal electrodes that have been deposited on the laser device.

The method of the present invention, in contrast, allows the nitride semiconductor layer(s) 2 to be grown over the laser facet 6 at a temperature of, for example, around 500° C. At such a temperature, damage to the processed laser structure is unlikely to occur. The reduction in growth temperature arises through use of MBE growth in which activated nitrogen is supplied as the nitrogen species for the overgrowth of the nitride layer(s) 2, since this eliminates the need for thermal activation of the nitrogen species.

In order to obtain the device shown in FIG. 2, a suitable nitride laser diode structure is grown as a wafer, and is then processed into conventional ridge waveguide laser bars as described by Kauer et al. in Electronics Letters, Vol. 41, No. 13, p37 (2005). In order to overgrow the facet protection layer on the processed laser bars according to a method of the present invention, the laser bars are inserted into the growth chamber of a MBE reactor such that the cleaved facets of the laser bars are exposed for crystal growth. The laser bars are heated to a growth temperature of approximately 500° C., and an AlGaN layer having a thickness of approximately 100 nm is deposited over the laser facet 6 by MBE. Activated nitrogen for the MBE growth is provided by a plasma cell, and aluminium and gallium are supplied by conventional MBE source cells (for example K-cells). The result of this growth step is the modified laser bar 1 shown in FIG. 2.

The modified laser bar 1 is then removed from the growth chamber of the MBE reactor and further processing steps may be carried out to form individual laser devices. The further processing steps may include, for example, coating the opposite end facet 6′ of each laser bar with a high reflectivity mirror (for example, a multi-layer dielectric Bragg mirror), and cleaving the laser bars into individual devices.

U.S. Pat. No. 6,812,152 discloses the formation of native nitride layers on at least one facet of a III-V semiconductor laser. This uses a nitridation method, in which a laser facet is bombarded with a nitrogen ion beam. This method is likely to lead to damage to the active region of the laser, and also can produce only thin nitride layers.

U.S. Pat. No. 6,670,211 discloses a method of growing a facet protection layer on a III-V laser diode, which requires the step of cleaving the wafer in-situ in a growth chamber to form the facet, followed by overgrowth of a facet protection layer. The in-situ facet cleaving step is, however, difficult to carry out. The method of the present invention does not require in-situ cleaving to expose a clean facet, because oxide formation on a nitride surface is low and the plasma nitridation step involved in the MBE growth process is sufficient to remove the native oxide from the facet. For example, the supply of activated nitrogen may be started before the supply of other elements, to remove the native oxide layer from the facet before the nitride overlayer(s) is grown although, since the native oxide layer is typically thin, this may not be necessary.

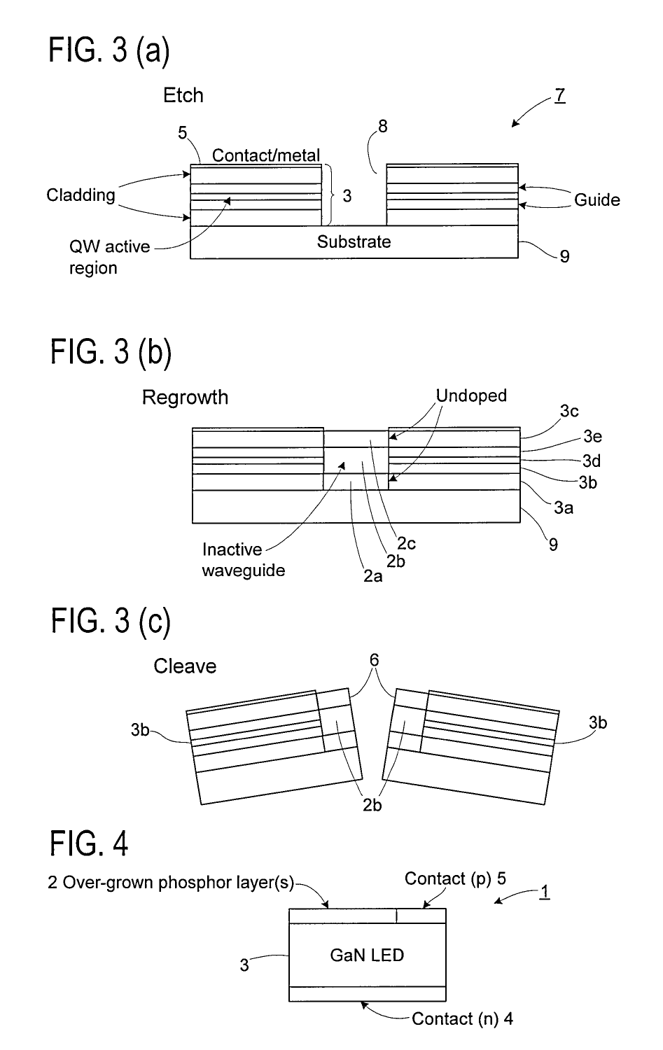

FIGS. 3(a) to 3(c) illustrates the principal steps of another method of the invention. This method again relates to growing a facet protection layer over a light-emitting facet of a nitride laser device. This method is performed on a nitride laser bar 7 which has been processed by depositing a contact 5 over a semiconductor laser diode structure 3, and which has also been processed by etching channels 8 having a chosen spacing (for example, 1 mm) between adjacent channels into the semiconductor laser diode structure 3 to reach the substrate 9 over which the laser structure 3 was grown. (Only one channel is shown in FIG. 3(a).) A typical width of a channel is 2 mm.

According to the present invention, the processed laser bar 7 of FIG. 3(a) is then subjected to overgrowth of nitride semiconductor layers that replicate the structure of the laser diode structure 3. These layers are grown in the channels 8. In the example of FIGS. 3(a) to 3(c), the laser structure 3 is shown as consisting of a lower cladding region 3a, an optical guiding region 3b, an active region 3d (in this example a quantum well active region) for light emission, an optical guiding region 3e, and an upper cladding region 3c—thus, the nitride layers that are overgrown include a first layer 2a that corresponds generally in composition and thickness to the lower cladding region 3a of the laser structure 3, a second layer 2b that corresponds generally in composition to the optical guiding regions 3b,3e of the laser structure 3 but that has a thickness equal to the combined thicknesses of the optical guiding region 3b, the active region 3d and the optical guiding region 3e, and a third layer 2c that corresponds generally in thickness and composition to the upper cladding region 3c of the laser structure 3. If the laser structure 3 should contain further layers, the nitride layers grown over the laser bar may preferably contain further layers corresponding in thickness, composition and location to these further layers of the laser structure 3. FIG. 3(b) shows the laser bar after the overgrowth of the nitride semiconductor layers 2a-2c.

In the example of FIGS. 3(a) and 3(b) the upper and lower cladding regions 3c,3a are nominally undoped. In this case, the first and third overgrown layers 2a,2c are therefore preferably also nominally undoped. The second overgrown layer 2b may also be nominally undoped.

The layer 2b grown in the channel 8 does not include an active layer for light emission, and so constitutes an “inactive waveguide” or a “passive waveguide”. The optical guiding region 3b, the active region 3d and the optical guiding region 3e of the laser structure are required to line up with, or line-up within, the inactive waveguide formed by layer 2b, so that light is guided efficiently.

Any material that is deposited on the contacts 5 during the step of overgrowing the nitride semiconductor layers 2a-2c can be removed by any suitable techniques such as, for example, wet or dry etching or a suitable lift-off technique.

The overgrown laser bar 7 is then cleaved through the channel 8 to define a facet 6 of an individual laser device.

The method of FIG. 3(a) to 3(c) has the advantage that the coating disposed on the laser facet contains an optical guide region 2b that extends parallel the light-emitting region 3b of the laser diode. This will improve the profile of the laser beam emitted by the resultant laser diode.

A further advantage of the method is that both facets of a laser diode can be coated in a single overgrowth step, so that the overgrowth procedure is therefore simplified and made quicker.

FIG. 4 is a schematic sectional view of a further nitride light-emitting device 1 which has been overgrown with one or more nitride semiconductor layers by a method of the present invention so as to modify the optical emission properties. FIG. 4 shows a device in which the nitride semiconductor layers(s) 2 have been grown over a top surface of the device, but this embodiment may alternatively be effected by growing the nitride semiconductor layer(s) 2 over a light-emitting facet of a light-emitting device.

In this embodiment of the invention, the layer(s) overgrown over the light-emitting device include at least one layer that is optically excited by light emitted by the light-emitting device when it is in use. This allows the spectrum of light emitted by the device to be modified. For example, in the case of a nitride laser device or light-emitting diode that emits blue light, the device may be overgrown with layers that include a layer that generates red light when excited by light from the laser diode or LED, a layer that generates light in the green region of the spectrum when excited by light emitted by the laser diode or LED, and a layer that emits light in the blue region of the spectrum when excited by light from the laser diode or LED—so that the laser diode or LED will output white light. (The overgrown layers will not absorb all the blue light emitted by the laser diode or LED, and the unabsorbed portion of the original output from the laser diode or LED will also contribute to the overall output from the device.)

One convenient way of obtaining a nitride semiconductor layer that is optically excited by light emitted by the light-emitting device when it is in use is to include a photoluminescent species into a nitride semiconductor layer. When the layer is irradiated with light, the photoluminescent species will absorb part of the light and re-radiate it.

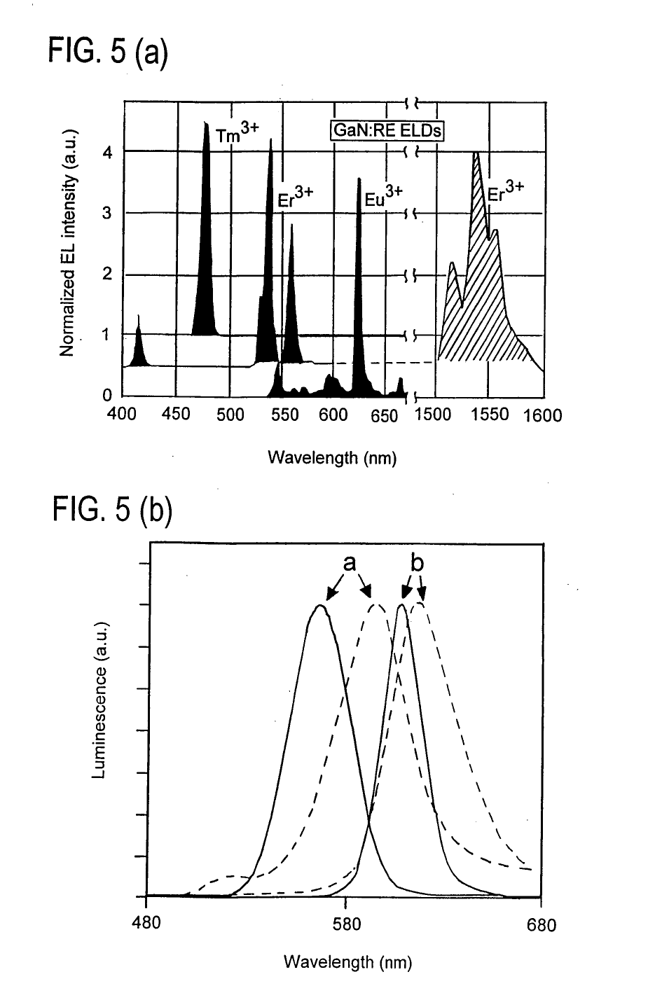

A suitable material for generating light in the red portion of the spectrum, when excited by blue light from a nitride laser diode or LED, is AlGaInN containing Europium as a photoluminescent species. Similarly, a layer of AlGaInN containing Erbium as a photoluminescent species will generate green light when excited by blue light from the nitride laser diodes or LED, and a layer of AlGaInN doped with Thulium as a photoluminescent species will emit light in the blue region of the spectrum when excited by the blue light from the nitride laser diode or LED. The blue light from the nitride laser diode or LED photo-pumps the radiative transitions of the rare earth dopant in the overgrown layer(s). FIG. 5(a) shows typical electroluminescence spectra for GaN doped with various rare earth elements. (Although this figure shows electroluminescence spectra, the corresponding photoluminescence spectra will be similar.)

To obtain the device shown in FIG. 4, the method of the invention is performed upon a nitride laser diode or LED structure that has been processed by providing electrodes 4, 5 over a semiconductor layer structure 3. The wafer has not yet been diced to form individual devices, and electrodes corresponding to a large number of laser diodes or LEDs are therefore provided on the wafer—however, only the electrodes corresponding to one laser diode or LED are shown in FIG. 4 for clarity. One or more nitride layers, denoted generally as 2 in FIG. 4, are then grown over a portion of the upper surface of the laser diode or LED as shown in FIG. 4, or are alternatively grown over a light-emitting facet of the device. The or each nitride semiconductor layer grown in this embodiment is a layer that re-emits light when optically excited by light from the laser diode or LED.

In a preferred embodiment the composition of the overgrown layer(s) 2 is/are selected such that the device outputs, in use, white light. The embodiment is not however limited to this, and the composition of the overgrown layer(s) 2 may alternatively be selected to provide any desired spectral characteristics.

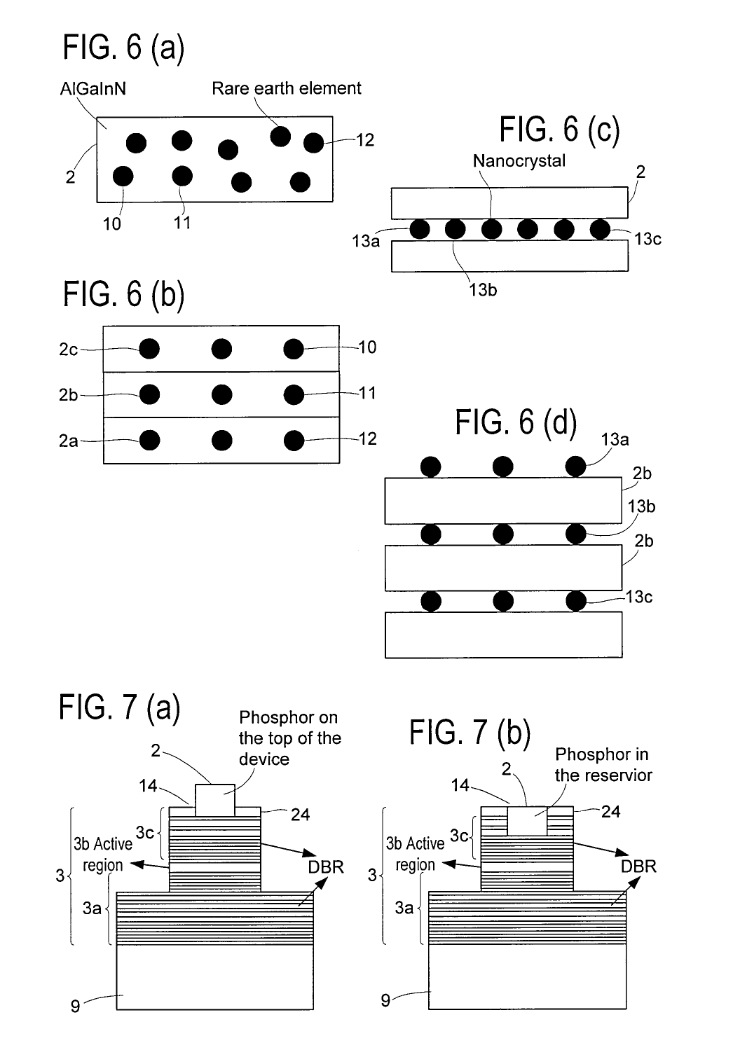

FIG. 6(a) illustrates one way in which a white light output can be obtained using a single nitride semiconductor layer 2. In this embodiment the nitride layer, in this embodiment an AlGaInN layer, contains three different rare earth elements 10,11,12 which, when excited by light from a laser diode or LED, re-emit light at three different wavelengths. Thus, when the layer 2 is illuminated by light from a laser diode or LED, the output light will include light re-emitted by the first rare earth element 10, light re-emitted by the second rare earth element 11, light re-emitted by the third rare earth element 12, and the part of the original output from the laser diode or LED that passes through the layer without absorption by a rare earth element 10-12.

FIG. 6(b) shows an alternative embodiment. In this embodiment, three separate nitride semiconductor layers 2a, 2b, 2c are deposited over the laser diode or LED. The first layer 2a contains one rare earth element 12 that emits light at a first wavelength when excited by light emitted by the laser diode or LED, the second layer 2b contains a second rare earth element 11 that emits light at a second wavelength, and the third nitride layer 2c contains a third rare earth element 10 that emits light at a third wavelength. In this embodiment, the nitride layers 2a, 2b, 2c may again be AlGaInN layers.

In a further embodiment, nanocrystals that re-emit light when excited by light from the laser diode or LED are deposited over the surface of the laser diode or LED, and the nanocrystals are then overgrown with a nitride semiconductor layer, for example an AlGaInN layer, according to the method of the invention. In this embodiment, the emission wavelength of the nanocrystals is determined by the size of the nanocrystals, so that a device which emits white light can be obtained by providing nanocrystals of three different sizes. FIG. 5(b) shows the photoluminescence and electroluminescence spectra of CdSe nanocrystals of two different sizes. In FIG. 5(b), the curves labelled “a” and “b” relate to 3.4 nm nanocrystals and 2.5 nm nanocrystals respectively. The full curves show photoluminescence spectra, and the broken curves show electroluminescence spectra.

In this embodiment, the nanocrystals may be deposited as a mixed layer that contains nanocrystals 13a, 13b, 13c of different sizes to another as shown in FIG. 6(c). The mixed layer of nanocrystals is then overlaid with a nitride layer 2, for example a AlGaInN layer. The mixed layer of nanocrystals may be disposed directly on the upper surface of an LED or laser diode, or it may be disposed on a nitride layer, for example an AlGaInN layer, that has been grown over the upper surface of an LED or laser diode.

Alternatively, the nanocrystals may be deposited in two or more separate layers, with each layer containing nanocrystals of one nominal size. Such an arrangement is shown in FIG. 6(d), in which the nanocrystals are arranged as a first layer of nanocrystals 13a of a first size, a second layer of nanocrystals 13b of a second size, and a third layer of nanocrystals of 13c of a third size. Each layer of nanocrystals is separated by a nitride semiconductor layer, for example an AlGaInN layer 2a, 2b. Each of the nitride semiconductor layers 2a, 2b is grown over a processed nitride laser diode or LED according to a method of the invention. If desired, a further nitride layer may be provided over the uppermost layer of nanocrystals.

In an embodiment in which nitride nanocrystals are used (for example InGaN nanocrystals), the nanocrystal layer(s) may be deposited according to a method of the invention, namely by growth using activated nitrogen in a vacuum chamber. In an embodiment in which non-nitride nanocrystals (for example, CdSe nanocrystals) are used, these must be deposited in a separate processing step.

A light-emitting device produced according to this embodiment of the present invention may be used to provide, for example, white lighting for homes and businesses, or back lighting for mobile devices and projectors. They can provide lower energy consumption and the current “hot filament” or gas discharge light sources. Moreover, these devices should have a longer lifetime, and are potentially more compact, then conventional LEDs.

The use of colloidal quantum dots, or nanocrystals, to convert the light emitted by a primary source of light into light of lower photon energy is described in, for example, U.S. Pat. Nos. 6,803,719 and 6 734 465. These disclose quantum dots or nanocrystals that are disposed within a host matrix, and convert light from a primary light source to light having a lower photon energy. In U.S. Pat. No. 6,734,465, the nanocrystals are doped with metal ions to control the emission wavelength, rather than varying the size of the nanocrystals to control emission wavelengths.

FIGS. 7(a) and 7(b) are schematic cross-sections of further examples of devices in which a phosphor layer is overgrown over a processed nitride light-emitting device according to a method of the present invention. In these embodiments, one or more nitride semiconductor layers, shown generally as 2, that re-emit light when excited by light from the light-emitting device, are grown over the processed light-emitting device. The light-emitting device may be, for example, a resonant cavity LED (RCLED) or a vertical cavity surface emitting laser (VCSEL). If a layer that re-emits light at a single wavelength is used a single colour light source may be obtained, but by using two or more nitride layers having different re-emission wavelengths a polychromatic light source or even a white light source can be obtained.

This embodiment is carried out on a laser device or LED that includes a semiconductor layer structure 3 grown over a substrate 9. The semiconductor layer structure 3 is shown as consisting of a lower cladding region 3a, an active region 3b and an upper cladding region 3c, with the cladding regions 3a,3c formed of layers stacked to form a distributed Bragg reflector (DBR), but the invention is not limited to this specific layer structure. The laser device or LED has been processed by inter alia, defining a channel 14 in the upper light-emitting surface region of the laser diode or LED. In FIG. 7(a) a channel 14 has been defined in the uppermost layer 24 of the layer structure 3, whereas in FIG. 7(b) a channel 14 that extends through the uppermost layer 24 and into the upper cladding region 3c of the device has been defined. One or more nitride layers, for example doped with one or more rare earth elements, are then overgrown into the channel 14 according to a method of the present invention to modify the emission characteristics of the laser device or LED. If a device that emits white light is desired, the nitride layer(s) may for example be arranged as shown in either FIG. 6(a) or 6(b). Alternatively, the nitride layer(s) may contain nanocrystals, for example as shown in FIG. 6(c) or 6(d).

The overgrown layer(s) may protrude above the upper layer 24 as shown in FIG. 7(a), or the upper surface of the overgrown layer(s) may be level, or substantially level, with the upper surface of the upper layer 24 as shown in FIG. 7(b).

A white light-emitting RCLED or a white light-emitting VCSEL offer the advantage of high extraction efficiency, emission from the upper surface, and a reduced emission area that aids effective coupling of light into a thin waveguide (for example less than 400 mm). The effective coupling of light into a thin waveguide is particularly useful when the devices are used as backlights for a liquid crystal display. A further advantage of this embodiment is that prior art attempts to provide a directional white light emitting LED have used an array of resonant cavity LEDs, in which each light may emit light of a different colour such that the overall output of the array appears to be white to an observer. Such an array is disclosed in U.S. patent application No. 2003/0209714. In a device according to the embodiment of FIG. 7(a) or 7 b), however, the RCLED or VCSEL emits a single wavelength of light, which then optically pumps the overgrown phosphor layer(s) in order to provide white light emission (or any other desired emission spectrum), and this is simpler and easier to fabricate.

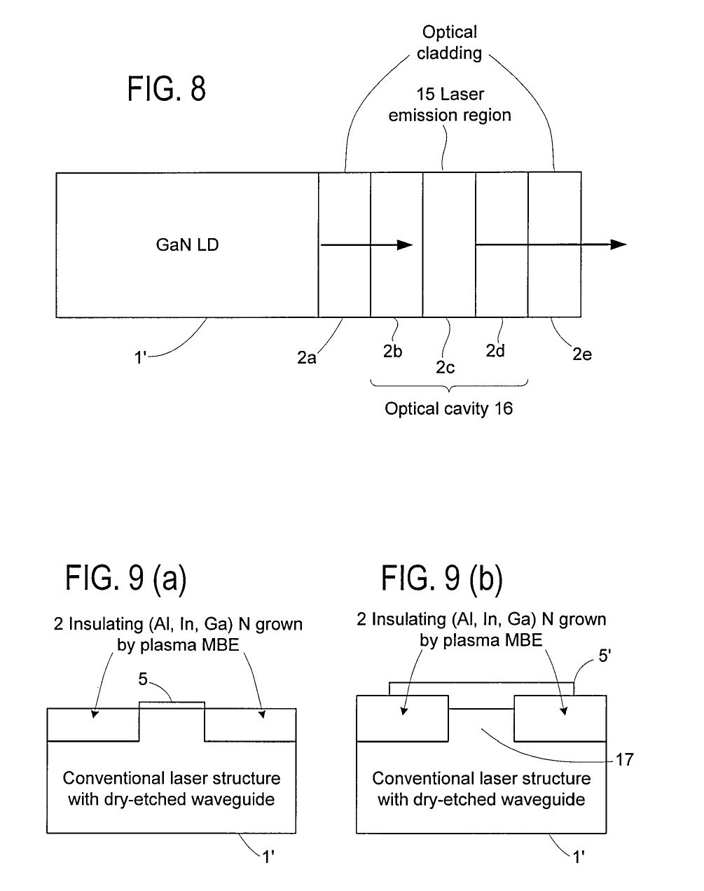

FIG. 8 shows a device that may be obtained according to a further embodiment of the present invention. According to this embodiment, a plurality of nitride layers 2a-2e are grown over the facet 6 of a processed nitride light-emitting device such as, for example, a processed nitride laser device 1′. The nitride layers 2a-2e grown in this embodiment constitute an optically pumped laser structure containing a laser emission region 15. In FIG. 8 the laser emission region 15 is shown as being constituted by one layer 2c of the overgrown nitride semiconductor layers, but the invention is not limited to this and the laser emission region may be formed by two or more nitride layers. The nitride layers 2a-2e constitute a facet coating for the light-emitting device 1′. The facets of the light-emitting device 1′ are the interface between the light-emitting device 1′ and the nitride layer 2a, and the far left surface of the light-emitting device 1′, and the optically pumped device formed by the nitride layers 2a-2e has facets at the interface between the light-emitting device 1′ and the nitride layer 2a and at the far right surface of the nitride layer 2e.

Light emitted by the nitride laser diode 1′ is absorbed in, and optically excites, the laser emission region 15 of the nitride layers 2a-2e. The emission region 15 is positioned inside an optical cavity 16, so as to generate laser emission. The emission region 15 may be, for example, a layer of AlGaInN doped with a rare earth element to obtain light emission at a desired wavelength. For example, if Erbium is used as the rare earth dopant in the AlGaInN emission region 15, a laser that emits light in the green wavelength region of the spectrum can be made. As further examples, if the laser diode 1′ emits light in the blue wavelength region of the spectrum, and an Erbium-doped AlGaInN emission region is disposed over one facet and a Europium doped AlGaInN emission region is disposed over another facet, then a laser having an output spectrum with emission components in the red, green and blue regions of the spectrum may be obtained. (The blue portion of the emission spectrum arises from some light from the laser diode 1′ that is not absorbed by the nitride layers 2a-2e and so contributes to the overall optical output of the device.)

In the structure shown in FIG. 8, the first and last layers of the nitride semiconductor layers 2a, 2e form cladding layers, and the layers 2b and 2d that surround the emission region 15 act as optical guiding regions that define the optical cavity 16. Where the emission region 15 is a suitably doped AlGaInN layer, AlGaInN is also a suitable material for the other layers 2a,2b,2d,2e but, as in a conventional laser diode, the bandgap of the cladding layers 2a,2e and optical guide layers 2b,2d needs to be greater than the photon energy of the emitted light in order to prevent absorption.

This embodiment is not limited to the use of a doped AlInGaN layer as the emission region 15. A single InGaN layer may be used as the emission region 15, or a multiple layer structure of InGaN/AlGaInN layers alternating with one another may be used. A typical overgrowth layer structure to obtain a laser device emitting in the green region of the spectrum would be AlGaN (cladding region 2a)—GaN (guiding region 2b)—InGaN (emission layer 2c)—GaN (guiding region 2d)—AlGaN (cladding region 2e). The GaN layers act as guiding layers, and the thicknesses of the GaN layers are chosen to create an optical cavity for the laser light emitted by the InGaN layer. The InGaN layer is preferably undoped.

As is the case when AlGaInN light emission layers are used, a laser emitting in the red, green and blue regions of the spectrum may also be made with InGaN emission regions, by providing a red emission layer on one facet of a blue laser diode and providing a green emission layer on an adjacent facet.

This embodiment of the invention may also be embodied using a laser emission region 15 that contains nanoparticles. In this embodiment, the first half portion of the cladding and cavity regions is grown by a method of the invention. The nanoparticles are then deposited on to the cavity, and the nanoparticles may, for example, be CdSe nanoparticles. Finally, the second part of the cavity and cladding regions is grown by a method of the invention.

Information about the doping of GaN and other materials with rare earth elements may be found in the article “Growth properties and fabrication of electroluminescent devices”, in IEE Journal of Selective Topics Quantum Electronics, Vol. 8 Jul. 2002.

FIGS. 9(a) and 9(b) show two further examples of devices obtained by method of the present invention. This embodiment is carried out on a nitride laser structure that has been processed to form a conventional buried heterostructure laser device, for example by using a dry etching technique to define the waveguide 17.

According to this embodiment of the invention, a layer 2 of insulating (Al,In,Ga)N is grown over the ridge waveguide structure 17 by a method of the invention so as to bury the ridge waveguide structure 17. The overgrown (Al,In,Ga)N material has a high thermal conductivity, so that the modified laser diode will have a much reduced thermal resistance compared to a conventional structure in which the ridge is coated with a dielectric material. This embodiment of the invention therefore allows a laser diode with a higher optical power and better mode control to be obtained.

This embodiment of the invention is typically carried out on a laser device that has been processed by metalising the top p-type surface of the wafer to form a p-type electrode 5, and etching the laser structure to define the ridge waveguide 17. The processed wafer is inserted into the growth chamber of a MBE reactor, with the metalised ridge surface exposed to source material. The growth temperature is raised to around 500° C., and an (Al,In,Ga)N layer 2, for example an AlGaN layer, is deposited over the upper surface of the laser diode wafer to a thickness equal to, or greater than, the height of the ridge waveguide 17. Activated nitrogen for the MBE growth is provided by a plasma cell, and aluminium and gallium are supplied by conventional MBE source cells. The overgrown structure is then removed from the MBE growth chamber, and the overgrown light (Al,In,Ga)N layer 2 is etched back until the metal layer 5 over the ridge waveguide 17 is exposed, to give a structure as shown in FIG. 9(a).

The laser diode structure can now be subject to further processing steps to provide individual laser devices. For example, the substrate of the laser structure can be thinned, a further metallic layer can be deposited over the upper surface of the structure to form an upper electrode, an electrode may be deposited on the bottom side of the device, the wafer may be cleaved to form individual devices, etc.

FIG. 9(b) shows a modification of the embodiment of FIG. 9(a). In this modified embodiment the overgrown layer 2 is etched back until its upper surface is at the same height as the upper surface of the metal layer 5. A further metal layer 5′ is then deposited over the original metal layer 5 and over at least part of the upper surface of the overgrown layer 2.

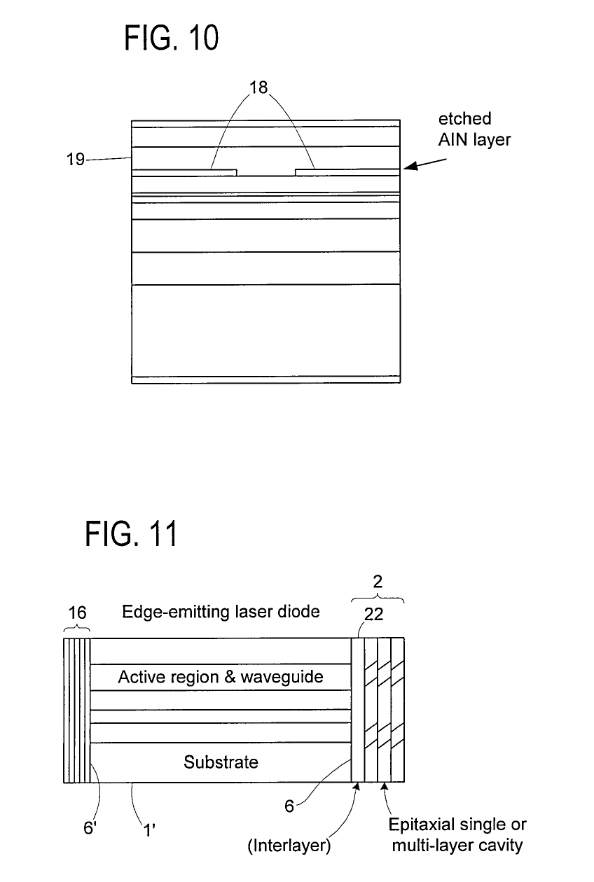

FIG. 10 shows a known device, disclosed in U.S. patent application No. 2005/0072986, which comprises an etched AlIn layer 18 that acts as a current confinement layer. An AlGaN cladding layer 19 is provided over the AlN current blocking layer by MOCVD. The AlGaN cladding layer 19 is doped p-type so as to be electrically conducting. A similar device is disclosed in Phys. Stat. Sol. Vol. 192, pp 329-334 (2002). This describes a laser diode having an overgrowth layer of etched SiO₂. Again, a conductive p-type overgrowth layer is required.

U.S. Pat. No. 6,567,443 describes a nitride laser diode in which a ridge waveguide structure is overlaid by a burying layer. This patent, however, uses an overgrowth temperature of up to 900° C., which can potentially lead to degradation of the processed laser diode.

In a further embodiment of the present invention, one or more nitride semiconductor layers are grown over a light-emitting facet of a nitride laser diode, to provide a device having the general form shown in FIG. 2 of the present application. In this embodiment, however, the layer(s) grown over the light-emitting facet include one or more layers that are absorbing for light emitted by the laser diode 1. The overgrown absorbing layer(s) absorbs the light from the laser until the layer becomes saturated, at which point laser light is then transmitted through the overgrown layer. If the overgrown layer(s) is arranged such that the life-time of carriers in the absorbing layer(s) is shorter than the carrier lifetime in the laser diode, the overgrown layer(s) will again start to absorb light from the laser. The overgrown layer(s) thus acts as a saturable absorber, and the device acts as a self pulsating laser device.

In this embodiment, the or each saturable absorbing layer can be, for example, an InGaN layer, or an InGaN/GaN multilayer structure may provide a plurality of saturable absorbing layers. If desired, a Bragg mirror structure can be grown over the saturable absorber layer(s), to create an optical cavity which will enhance the self-pulsation effect. The Bragg mirror can be formed of, for example, an AlGaN/GaN multilayer structure.

As is known, a self-pulsating laser diode has reduced noise in optical pickup systems, so that no expensive feedback circuitry is required. This embodiment of the invention provides a simple way to manufacture a self-pulsating laser diode.

FIG. 11 is a schematic cross-section of a further device that can be obtained by a method of the present invention. The device shown in FIG. 11 comprises a processed edge-emitting nitride laser device 1′ having one or more nitride semiconductor layers denoted generally by 2 disposed over one facet 6 of the laser device 1′.

The nitride layer(s) form an optical cavity that acts to filter light emitted by the laser 1′ such that the cavity transmits light only in a very narrow frequency range. Thus, the device of FIG. 11 can provide single wavelength laser operation, for example for use in optical data storage systems.

The optical cavity may be formed by a single nitride semiconductor layer (i.e., as an epitaxial single layer cavity), or by two or more nitride semiconductor layers (i.e., as an epitaxial multi-layer cavity) as shown in FIG. 11. A typical material for the semiconductor layers is GaN, with the cavity layer or layers having an optical thickness that is a multiple of the desired output wavelength.

This embodiment of the invention is effected on a processed edge emitting laser diode. The nitride layer(s) 2 forming the optical cavity are disposed on the facet 6 of the laser diode according to a method of the present invention, in which the layers are grown in a vacuum chamber using a nitrogen plasma to provide the nitrogen for the growth process.

A reflective structure, such as a Bragg mirror, may be disposed on the opposite end facet 6′ of the laser. In this case, the layers 16 forming the reflective structure are preferably deposited by a method of the present invention.

An “interlayer” 2z may be deposited on the facet of the nitride device 1′ before the nitride layers that form the optical cavity are deposited. This may improve the optical cavity region by ensuring that the cavity is deposited over a surface that has a uniform composition, e.g. AlGaN.

Laser structures provided with a cavity for filtering the output wavelength or mode of light from the laser are known, for example from U.S. Pat. Nos. 5,629,954 and 6,647,046. These prior art devices use dielectric layers for the cavity, but dielectric layers have the disadvantages of poor thermal conductivity and poor thermal mismatch with the materials of the laser device.

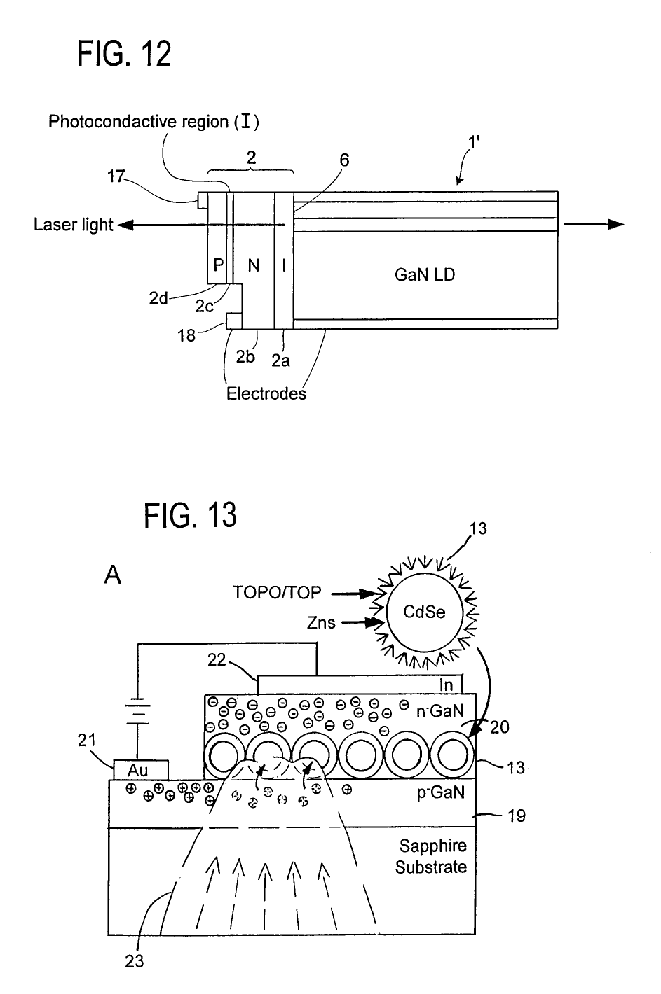

FIG. 12 is a schematic cross-section of a structure that can be obtained by a further embodiment of the present invention. In this embodiment, a plurality of nitride semiconductor layers, denoted generally as 2, are grown over a light-emitting facet 6 of a processed nitride light-emitting device 1′ such as a nitride laser diode. In the device shown in FIG. 12, the nitride layer(s) 2 grown over the light-emitting facet constitute a light-sensitive device such as, for example, a photodiode. In the particular embodiment of FIG. 12, four nitride layers have been grown over the end facet 6 of the laser diode 1 being, in order, an insulated layer 2a, an n-type doped layer 2b, a photoconductive layer 2c, and a p-typed doped layer 2d. The layers 2a-2d may be, for example, (Al,Ga,In)N layers, and the photoconductive layer 2c can be chosen to suit the emission wavelength of the laser 1. In many embodiments, an InGaN photoconductive layer 2c is suitable—this may in principle be used for any emission wavelength less than 1800 nm (which corresponds to use of InN for the photoconductive layer 2c).

First and second electrodes 17, 18 are provided on opposite sides of the photoconductive layer 2c. In the embodiment of FIG. 12, one electrode 17 is provided on the p-type layer 2d and a second electrode 18 is provided on the n-type layer 2d. This allows the current generated in the photoconductive region 2c to be measured or monitored.

In use, when the laser 1′ is operating light from the laser will pass through the photoconductive region 2c and generate an electrical current. The magnitude of the current generated in the photoconductive region 2c will depend upon the intensity of light output from the laser device 1′. Thus, the performance of the laser can be monitored and any abnormalities in operation of the laser can be noted to give warning of any possible failure of the laser. If desired, a feedback loop can be provided between the output current from a photodiode and the drive current for the laser device 1′, in order vary the drive current to the laser in order to maintain a constant intensity of light output from the laser. The overgrowth layers thus improve the optical output stability of the laser, as part of a feedback circuit of which they are a critical element.

It has been known to provide a laser device with a separate monitor photodiode, and this is disclosed in, U.S. Pat. No. 5,032,879. However, in these prior lasers, the photodiode is not integrated with the laser diode. Fabricating the laser 1′ and photodiode in a single component reduces the overall size of the component. Moreover the photoconductive region 2c of the photodiode is in a plane that is normal to the direction of output light from the laser device, and this will maximise the magnitude of the photo-current generated in the photoconductive layer 2c.

The nitride layers 2a-2d may be deposited by a method of the present invention, by introducing the processed laser diode 1′ into a vacuum chamber and depositing the nitride semiconductor layers 2a-2d using a plasma assisted growth method.

The embodiment of FIG. 12 is not limited to the specific photodiode structure shown in FIG. 12. For example, a p-i-n-i photodiode structure, in which a further insulating layer is disposed of between the p-type layer 2d and the n-type layer 2b could alternatively be used.

In a device grown by a further embodiment of the present invention, the device is similar to that shown in FIG. 4 in that it has one or more over-grown phosphor layers disposed over a light-emitting surface of a laser diode or LED. The phosphor layers contain nanocrystals and, in this further embodiment, the nanocrystals are electrically pumped to generate light. A device having this general form is known, for example from the article by A. H. Mueller in Nanoletters Vol. 5, ppP1039 (2005), from which FIG. 13 is taken. In the device from FIG. 13, nanocrystals 13 are encapsulated in a GaN p-n junction, at the interface between a p-type GaN layer 19 and an p-type GaN 20. The nanocrystals 13 are electrically pumped by means of electrodes 21, 22 provided on the n-type and p-type GaN layers, so as to emit light indicated generally at 23.

In the prior art of Mueller, a low temperature atomic beam epitaxy process is used to overgrow the nanocrystals 13 at a temperature of 500° C. or below. The growth technique of Mueller is, however, limited to n-doped GaN.

According to the present invention, a device similar to that shown in FIG. 13 can be grown by initially depositing a p-type nitride layer, for example a p-type GaN layer, over a suitable substrate by any conventional growth technique such as MBE or MOCVD. The device is then processed by depositing nanocrystals 13 over the p-type layer to form a processed light-emitting device. The nanocrystals may be deposited from an organic solution—for example, a solvent solution containing the nanocrystals may be applied to the surface of the device.

The n-type layer is then overgrown over the nanocrystals by a method of the present invention—that is, the structure is introduced into a vacuum chamber, and the n-type layer 20 is grown using a plasma-assisted growth process. This allows the device to be fabricated in a wider range of material systems rather than just GaN.

In this embodiment, the nanocrystals can be CdSe nanocrystals or InGaN nanocrystals. They may reside in a p-n structure similar to that shown in FIG. 13, or they may reside in a p-i-n structure in which an insulating layer is provided between the p-type layer and the p-type layer.

The present invention is not limited to the description of the embodiments above, but may be altered by a skilled person within the scope of the claims. An embodiment based on a proper combination of technical means disclosed in different embodiments is encompassed in the technical scope of the present invention.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

What is claimed is:

1. A method of modifying the optical emission properties of a processed nitride semiconductor light-emitting device, the method comprising the steps of:
a) disposing the processed nitride semiconductor light emitting device in a vacuum chamber; and
b) growing one or more nitride semiconductor layers on said processed nitrides semiconductor light-emitting device by molecular beam epitaxy thereby to modify the optical properties of the processed light-emitting device;
wherein the method further comprises supplying activated nitrogen to the vacuum chamber in step (b).

2. A method as claimed in claim 1 wherein step (b) comprises growing the one or more nitride semiconductor layers by plasma-assisted molecular beam epitaxy.

3. A method as claimed in claim 1 wherein step (b) comprises growing the one or more nitride semiconductor layers over a light-emitting facet of the light-emitting device.

4. A method as claimed in claim 3 wherein the or each nitride semiconductor layer has a bandgap greater than the emission photon energy of the light-emitting device.

5. A method as claimed in claim 1 wherein the or each nitride semiconductor layer is, in use, optically excited by light emitted by the light-emitting device.

6. A method as claimed in claim 5 wherein the or each nitride semiconductor layer contains a photoluminescent species.

7. A method as claimed in claim 6 wherein step (b) comprises growing a nitride semiconductor layer containing two or more photoluminescent species.

8. A method as claimed in claim 6 wherein step (b) comprises growing two or more nitride semiconductor layers each containing a respective photoluminescent species.

9. A method as claimed in claim 6 wherein step (b) comprises growing the nitride semiconductor layer(s) over nanocrystals deposited on the processed nitrides semiconductor light-emitting device.

10. A method as claimed in claim 9 wherein the nanocrystals deposited on the processed nitrides semiconductor light-emitting device comprise at least first nanocrystals having a first size and second nanocrystals having a second size different from the first size.

11. A method as claimed in claim 3 wherein the nitride semiconductor layer(s) comprise at least one saturable absorbing layer.

12. A method as claimed in claim 3 wherein the nitride semiconductor layer(s) define an optical cavity.

13. A method as claimed in claim 12 wherein step (b) comprises depositing a plurality of nitride semiconductor layers, and wherein at least one of the nitride semiconductor layers is, in use, optically excited by light emitted by the light-emitting device.

14. A method as claimed in claim 3 wherein the nitride semiconductor layer(s) define a wavelength filter.

15. A method as claimed in claim 3 wherein the nitride semiconductor layer(s) comprise a light-sensitive layer.

16. A method as claimed in claim 15 wherein the nitride semiconductor layers define a photodiode.

17. A method as claimed in claim 1 wherein the processed nitride semiconductor light-emitting device comprises a ridge waveguide, and step (b) comprises growing the one or more nitride semiconductor layers over the surface of the device on which the ridge waveguide is provided.

18. A method as claimed in claim 17 wherein the or each nitride semiconductor layer is electrically insulating.
